(19) United States
(12) Patent Application Publication
(10) Pub. No.: US 2023/0069259 A1
(43) Pub. Date: Mar. 2, 2023

(54) MICROCONTROLLER WITH TRACTION INVERTER PROTECTION

(71) Applicant: Texas Instruments Incorporated, Dallas, TX (US)

(72) Inventors: Huihuang CHEN, Shenzhen (CN); Subrahmanya Bharathi AKONDY, Cypress, TX (US); Rui WANG, Shanghai (CN)

(21) Appl. No.: 17/462,898

(22) Filed: Aug. 31, 2021

(51) Int. Cl. H03K 17/082

(52) U.S. Cl. CPC H03K 17/082; H03K 2217/0063; H03K 2217/0072

(57) ABSTRACT

An integrated circuit includes: a control signal output; a pulse-width modulation (PWM) subsystem with a PWM input and a PWM output, the PWM output configured to provide PWM control signals; and configurable logic (CL) with a first CL input, a second CL input, and a CL output. The first CL input is coupled to the PWM output, the second CL input is adapted to receive a fault indicator. The CL output is coupled to the control signal output. The CL is configured to provide the PWM control signals to the control signal output unless the fault indicator indicates a fault.

### BACKGROUND

As new electronic devices are developed and integrated circuit (IC) technology advances, new IC products are commercialized. One example IC is a microcontroller configured to provide pulse-width modulation (PVVM) control Signals (e.g., a 6-channel PWM output) for a traction inverter. The traction inverter uses the PWM control signals to provide current (e.g., different phase currents) to a motor. For example, in an electric vehicle scenario, the traction inverter uses the PWM control signals to provide current from the vehicle's battery to a drivetrain motor.

To detect fault conditions (e.g., overcurrent, overvoltage, or a traction inverter fault) and provide a response, a conventional approach uses a separate IC between the microcontroller and the traction inverter. FIG. 1 shows a system 100 in accordance with a conventional approach. As shown, the system 100 includes a microcontroller 102 with a PWM subsystem 104, a serial peripheral interface (SPI) subsystem 106, and an input/output (I/O) subsystem 108. The PWM subsystem 104 is configured to provide PWM control signals. The SPI subsystem 106 is configured send or receive communications via a serial interface according to the SPI protocol. The I/O subsystem 108 is configured to send or receive information via available I/O ports. Together, the SPI subsystem 106 and the I/O subsystem 108 introduce latency 109 in the fault detection process.

In the example of FIG. 1, the microcontroller 102 is coupled to a complex programmable logic device (CPLD) 110. The CPLD 110 is configured to receive the PWM control signals from the PVVM subsystem 104 of the microcontroller 102. The CPLD 110 also receives a speed level indication from the I/O subsystem 108 of the microcontroller 102. In addition, the CPLD 110 receives a switch fault signal, an overcurrent protection (OCP) signal, and an overvoltage protection (OVP) signal. The CPLD 110 also provides status information to the microcontroller 102 via the SPI subsystem 106 of the microcontroller 102. In operation, the CPLD 110 provides control signals to the traction inverter 112, where the control signals vary depending on whether there is a fault condition and the fault condition type. If there is no fault, the CPLD 110 provides the PWM control signals to the traction inverter 112. In such case, the traction inverter 112 uses the PWM control signals to provide current to a motor 114 coupled to the traction inverter 112. If a fault condition is detected, the CPLD 110 does not forward the PWM control signals to the traction inverter 112. Instead, the CPLD 110 provides control signals that cause one or more switches of the traction inverter 112 to transition to and stay in a high-state or a low-state responsive to the particular fault condition detected. In this manner, the traction inverter 112 is protected from damage due to the fault conditions. Efforts to reduce the cost and latency of motor control and traction inverter protection are ongoing.

### SUMMARY

In an example embodiment, an integrated circuit comprises: a control signal output; a pulse-width modulation (PWM) subsystem with a PWM input and a PWM output, the PWM output configured to provide PWM control signals; and configurable logic (CL) with a first CL input, a second CL input, and a CL output. The first CL input is coupled to the PWM output. The second CL input is adapted to receive a fault indicator. The CL output is coupled to the control signal output. The CL is configured to provide the PWM control signals to the control signal output unless the fault indicator indicates a fault condition.

In another example embodiment, a system comprises a microcontroller having: a control signal output adapted to be coupled to a traction inverter; a PWM subsystem configured to provide PWM control signals; and CL. The CL is configured to: receive the PWM control signals and a fault indicator; and provide the PWM control signals to the control signal output unless the fault indicator indicates a fault condition.

In yet another example embodiments, a method comprises: generating, by a microcontroller, PWM control signals; and detecting, by the microcontroller, if there is a fault condition associated with the traction inverter. The method also comprises: providing, by the microcontroller, a traction inverter protection signal to the traction inverter if the fault condition is detected; and providing, by the microcontroller, the PWM control signals to the traction inverter if the fault condition is not detected.

### BRIEF DESCRIPTION OF THE DRAWINGS

For a detailed description of various examples, reference will now be made to the accompanying drawings in which:

FIG. 1 is a block diagram showing a system in accordance with a conventional approach.

FIG. 2 is a block diagram showing a system in accordance with an example embodiment.

FIG. 3 is a block diagram showing a microcontroller with traction inverter protection in accordance with an example embodiment.

FIG. 4 is a flowchart showing a traction inverter protection method in accordance with an example embodiment.

FIGS. 5A-5D are graphs showing a fault condition waveform and related traction inverter control signals in accordance with an example embodiment.

FIG. 6 is a flowchart showing a traction inverter protection method performed by a microcontroller in accordance with an example embodiment.

The same reference number is used in the drawings for the same or similar (either by function and/or structure) features.

### DETAILED DESCRIPTION

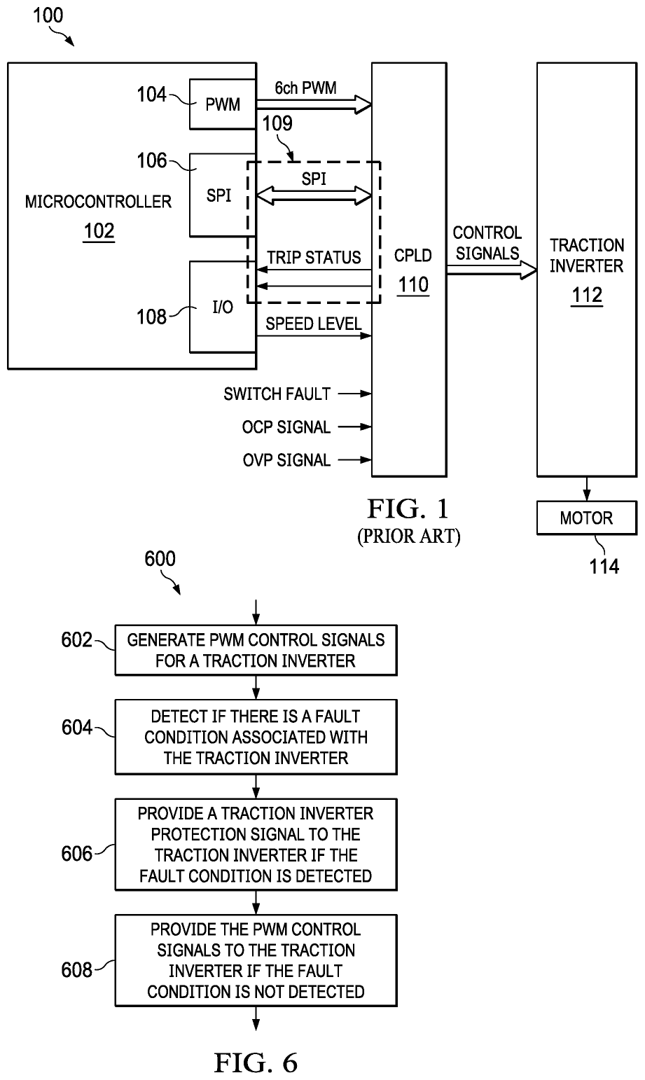

In some example embodiments, a microcontroller includes traction inverter protection. The microcontroller is, for example, an integrated circuit (IC) included with an electric vehicle or other system with a motor controlled by a traction inverter. During normal operations, the microcontroller is configured to provide pulse-width modulation (PWM) control signals to a traction inverter based on motor position information, a target speed relative to a current speed, and/or other control schemes. In addition, the microcontroller is configured to detect different fault conditions for the traction inverter. In response to the different fault conditions, the microcontroller may turn switches of the traction inverter on or off in accordance with a predetermined program or state machine. By adding traction inverter protection to the microcontroller, the cost and latency of traction inverter protection is reduced compared to conventional approaches (see e.g., FIG. 1).

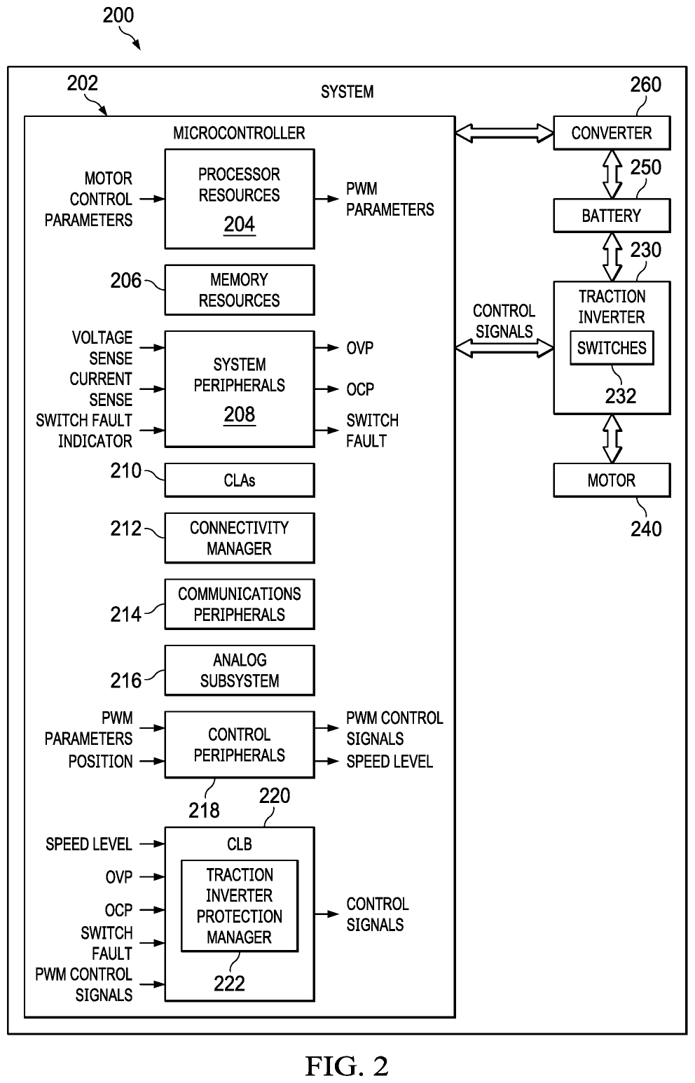

FIG. 2 is a block diagram showing a system 200 in accordance with an example embodiment. In some example embodiments, the system 200 is an electric vehicle or other system with a motor 240. In the example of FIG. 2, the system 200 includes a battery 250 to provide power to the motor 240 as well as other electronic components of the system 200. As desired, a voltage converter 260 (or multiple voltage converters) may be used to convert the voltage of the battery 250 to another voltage value for use by a microcontroller 202 and/or other components. To control the motor 240, a traction inverter 230 provides current from the battery 250 to the motor 240 using switches 232. The switches 232 of the traction inverter 230 include, for example, high-side switches and low-side switches for each current phase used to control the motor 240. In some example embodiments, the switches 232 are insulated-gate bipolar transistors (IGBTs).

In the example of FIG. 2, the microcontroller 202 is used to control the switches 232 of the traction inverter 230. Relative to the microcontroller 102 in the conventional example of FIG. 1, the microcontroller 202 of FIG. 2 adds on-chip traction inverter protection. As shown, the microcontroller 202 includes processor resources 204 (e.g., one or more processors). Without limitation, the processor resources 204 may include 32-bit processors with floating point, trigonometric, division, and/or other computation units. In some example embodiments, the processor resources 204 are configured to determine PWM parameters (e.g., a PWM duty cycle) from motor control parameters (e.g., a target speed relative to a current speed). The microcontroller 202 also includes memory resources 206 to store instructions and values for use by the processor resources 204. Without limitation, examples of the memory resources 206 include: local random-access memory (RAM); shared RAM; and/or other memory options.

The microcontroller 202 also includes system peripherals 208. Without limitation, examples of the system peripherals 208 include: external memory interfaces; direct memory access (DMA) controllers; general purpose input/output (GPIO) ports; comparators (CMPSS); and/or other peripheral support components. In some example embodiments, the system peripherals 208 are configured to: generate an OVP signal based on a received voltage sense value and a threshold; generate an OCP signal based on a received current sense value and a threshold; and generate a switch fault signal based on a received switch fault indicator.

In the example of FIG. 2, the microcontroller 202 may also include control law accelerators (CLAs) 210 to support concurrent processing of control algorithms by the CLAs 210 and the processor resources 204. As shown, the microcontroller 202 further includes a connectivity manager 212 configured to support network communications. Without limitation, example components of the connectivity manager 212 include: a processor; memory (e.g., flash memory); an Advanced Encryption Standard (AES) accelerator; a cyclic redundancy check (CRC) manager; a DMA controller; a Universal Asynchronous Receiver/Transmitter (UART) interface; a serial communication interface; an Ethernet interface; and/or a Controller Area Network (CAN) interface. The microcontroller 202 also includes communication peripherals 214. Without limitation, examples of the communication peripherals include: channel specific serial communication interfaces; shared serial communication interfaces; and related transmitters, receivers, and/or ports. The microcontroller 202 further includes an analog subsystem 216. Without limitation, the analog subsystem 216 includes: analog-to-digital converter (ADCs), sample-and-hold (S/H) circuits, digital-to-analog converter (DACs), and related inputs/outputs.

In the example of FIG. 2, the microcontroller 202 also includes control peripherals 218 configured to generate PWM control signals based on the PWM parameters provided by the processor resources 204. The control peripherals 218 are further configured to generate a speed level based on position information obtained from motor phase current analysis. Without limitation, example components of the control peripherals 220 include: PWM channels, Enhanced Capture (eCap) modules, Enhanced Quadrature Encoder Pulse (eQEP) modules with a resolver decoder, and Sigma-Delta Filter Module (SDFM) channels.

The microcontroller 202 additionally includes configurable logic (CL), referred to as a configurable logic block (CLB) 220 in FIG. 2. As shown, the CLB 220 receives the speed level, the OVP signal, the OCP signal, the switch fault signal, and the PWM control signals as inputs. In some examples, the CLB 220 includes a traction inverter protection manager 222 configured to perform traction inverter protection operations based on the speed level, the OVP signal, the OCP signal, and the switch fault signals. In some example embodiments, the traction inverter protection operations provide the PWM controls signals as the control signals to the traction inverter 230 if a fault indicator (e.g., certain combinations of the speed level, the OVP signal, the OCP signal, and/or the switch fault signals) indicates that there is no fault. If the fault indicator (e.g., other combinations of the speed level, the OVP signal, the OCP signal, and/or the switch fault signals) indicates that there is a fault, the CLB 220 is configured to provide traction inverter protection signals as the control signals for the traction inverter 230. Example traction inverter protection signals include: low-side on and high-side off control signals; low-side off and high-side on control signals; and low-side off and high-side off control signals. In some example embodiments, the CLB 220 is configured to use the speed level, the OCP signal, the OVP signals, and the switch fault signal to: detect whether there is a fault condition; determine a fault condition type; and provide a related response (e.g., provide the PWM control signals if there is no fault condition detected, or provide traction inverter protection signals based on the fault condition type detected).

In some example embodiments, the traction inverter protection manager 222 is a state machine implemented in hardware, firmware, and/or software of the CLB 220. The CLB 220 may be, for example, a collection of configurable blocks that can be interconnected using software to implement custom digital logic functions. In some example embodiments, the CLB 220 is able to enhance existing peripherals through a set of crossbar interconnections, which provide a high level of connectivity to existing control peripherals such as enhanced pulse width modulator (ePWM) modules, eCAP modules, and eQEP modules. The crossbars also allow the CLB 220 to be connected to external GPIO pins. In this manner, the CLB 220 can be configured to interact with device peripherals to perform small logical functions such as simple PWM generators, or to implement custom serial data exchange protocols.

In operation, the CLB 220 with the traction inverter protection manager 222 is configured to receive the PWM control signals, the speed level, the OCP signal, the OVP signal, and the switch fault signal. Based on the PWM control signals, the speed level, the OCP signal, the OVP signal, and the switch fault signal, the CLB 220 with the traction inverter protection manager 222 is configured to: detect whether there is a fault condition; determine a fault condition type; and provide a related response. If there is no fault condition, the CLB 220 provides the PWM control signals as the control signals for the traction inverter 230. If there is fault condition, the CLB 220 is configured to provide traction inverter protection signals (e.g., low-side on and high-side off control signals; low-side off and high-side on control signals; or low-side off and high-side off control signals) as the control signals to the traction inverter 230. The particular traction inverter protection signals vary depending on the fault condition type as described herein.

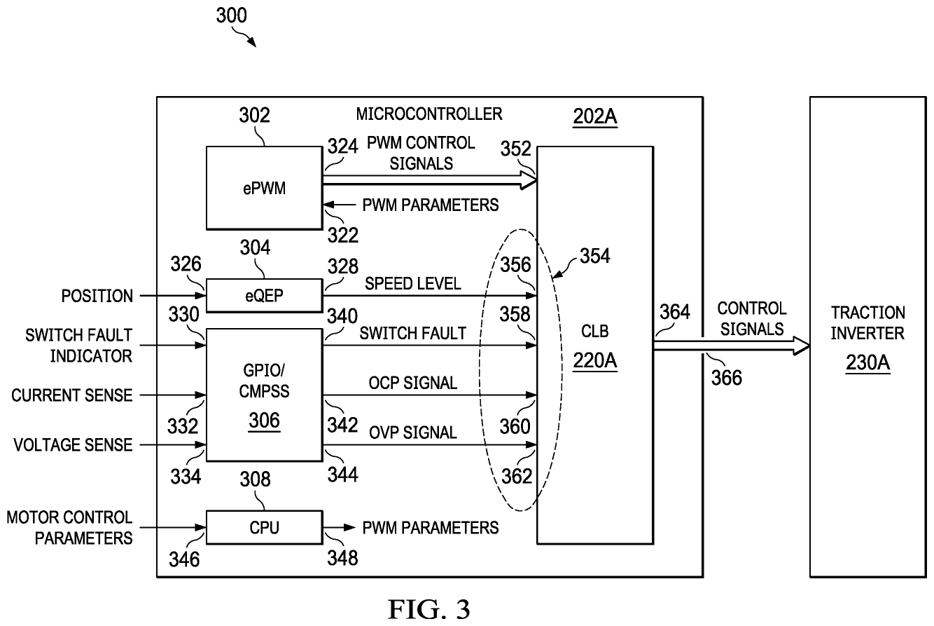

FIG. 3 is a block diagram showing a microcontroller 202A (an example of the microcontroller 202 in FIG. 2) with traction inverter protection in accordance with an example embodiment. In the example of FIG. 3, the microcontroller 202A is configured to received various inputs including: a position indicator; a switch fault indicator; a current sense value; a voltage sense value; and motor control parameters. Based on the inputs, the microcontroller 202A is configured to generate various signals including the PWM control signals, a speed level, a switch fault signal, the OCP signal, and the OVP signal. As shown, the microcontroller 202A includes a control signal output 366 coupled to a traction inverter 230A (an example of the traction inverter 230 in FIG. 2). In operation, the microcontroller 202A is configured to provide control signals to the traction inverter 230A via the control signal output 366. The control signals provided to the traction inverter 230A are the PWM control signals if no fault condition is detected. If a fault condition is detected, different traction inverter protection signals (e.g., low-side on and high-side off control signals; low-side off and high-side on control signals; or low-side off and high-side off control signals) are provided to the traction inverter 230A depending on the fault condition type detected.

More specifically, the microcontroller 202A includes an ePWM subsystem 302 (e.g., part of the control peripherals 218 in FIG. 2). The ePWM subsystem 302 is configured to generate PWM control signals at ePWM output 324 based on PWM parameters received at ePWM input 322. For example, the PWM parameters indicate a PWM duty cycle or indicate whether the PWM duty cycle should increase or decrease (to increase or decrease motor speed relative to a target). The microcontroller 202A also includes an eQEP subsystem 304 (e.g., part of the control peripherals 218 in FIG. 2). The eQEP subsystem is configured to generate a speed level at eQEP output 328 based on position information received at eQEP input 326.

As shown, the microcontroller 202A additionally includes a GPIO/CMPSS subsystem 306. The GPIO/CMPSS subsystem 306 may be part of the system peripherals 208 of FIG. 2. In the example of FIG. 3, the GPIO/CMPSS subsystem 306 is configured to provide a switch fault signal at GPIO output 340 based on a switch fault indicator received at GPIO input 330. The GPIO/CMPSS subsystem 306 is also configured to provide an OCP signal at GPIO output 342 based on a current sense signal received at GPIO input 332 and a threshold. For example, a comparator of the GPIO/CMPSS subsystem 306 may output an asserted OCP signal if the current sense signal is greater than the threshold. Otherwise, the OCP signal is de-asserted. The GPIO/CMPSS subsystem 306 is additionally configured to provide an OVP signal at GPIO output 344 based on a voltage sense signal received at GPIO input 334 and a threshold. For example, a comparator of the GPIO/CMPSS subsystem 306 may output an asserted OVP signal if the voltage sense signal is greater than the threshold. Otherwise, the OVP signal is de-asserted. As shown, the microcontroller 202A further includes a processor (CPU) 308 configured to provide the PWM parameters at processor output 348 based on motor control parameters received at processor input 346. The motor control parameters may include, for example, a target speed relative to a current speed, or other motor control parameters.

In the example of FIG. 3, the PWM control signals, the speed level, the switching fault signal, the OCP signal, and the OVP signal are provided to a CLB 220A (an example of the CLB 220 in FIG. 2). More specifically, the PWM control signals are provided to a first CLB input 352 of the CLB 220A while the speed level, the switching fault signal, the OCP signal, and the OVP signal are provided to a second CLB input 354 of the CLB 220A. In some example embodiments, the second CLB input 354 includes separate inputs 356, 358, 360, and 362 for each of the speed level, the switching fault signal, the OCP signal, and the OVP signal. As another option, the second CLB input 354 may be a single input coupled to the speed level, the switching fault signal, the OCP signal, and the OVP signal via a multiplexer or other logic. Another option is for the CLB 220A to decode a packet received by the second CLB input 354 to obtain the speed level, the switching fault signal, the OCP signal, and the OVP signal from other components of the microcontroller 202A. In some example embodiments, the CLB 220A is able to enhance existing peripherals through a set of crossbar interconnections, which provide a high level of connectivity to existing control peripherals such as ePWM modules, eCAP modules, and eQEP modules. The crossbars also allow the CLB 220A to be connected to external GPIO pins.

In operation, the CLB 220A is configured to provide control signals to a CLB output 364 coupled to the control signal output 366 of the microcontroller 202A. The control signals provided to the traction inverter 230A are based on the PWM control signals and fault condition detection. If no fault condition is detected, the PWM control signals are provided as the control signals to the traction inverter 230A. If there is a fault condition detected, the PWM control signals are not provided to the traction inverter 230A. Instead, traction inverter protection signals (e.g., low-side on and high-side off control signals, low-side off and high-side on control signals, or low-side off and high-side off control signals) are provided as the control signals for the traction inverter 230A. The particular traction inverter protection signals provided to the traction inverter 230A in response to a fault condition depends on the fault condition type, which can be determined using the speed level, the switching fault signal, the OCP signal, and/or the OVP signal.

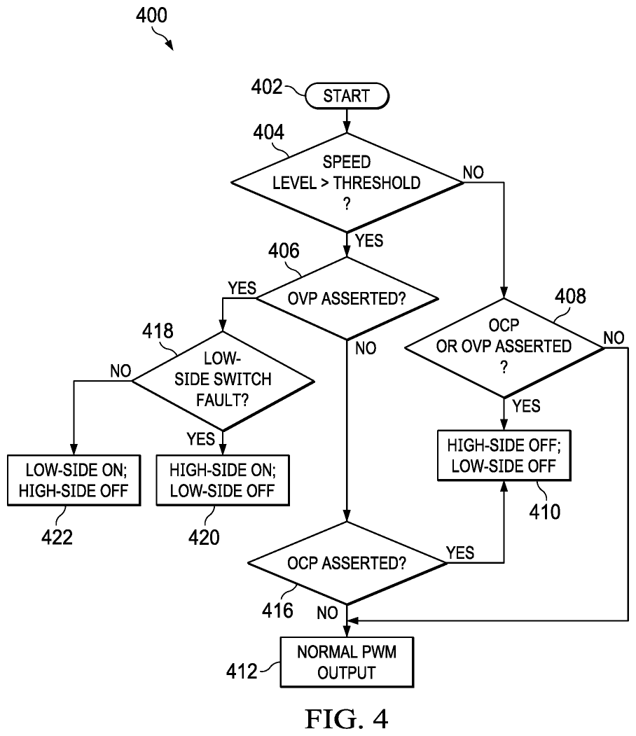

FIG. 4 is a flowchart showing a traction inverter protection method 400 in accordance with an example embodiment. The traction inverter protection method 400 may be performed, for example, by configurable logic (e.g., the CLB 220 of FIG. 2, or the CLB 220A of FIG. 3) of a microcontroller (e.g., the microcontroller 202 in FIG. 2, or the microcontroller 202A in FIG. 3). As shown, the traction inverter protection method 400 begins at start block 402. At determination block 404, the speed level is compared with a threshold. If the speed level is less than the threshold (determination block 404) and the OCP signal or the OVP signal is asserted (determination block 408), high-side off and low-side off control signals are provided to a traction inverter at block 410. In some example embodiments, block 410 corresponds to a first fault condition type called “shut-down” (to turn off all switches of the traction inverter). If the OCP signal or the OVP signal is not asserted (determination block 408), the PWM control signals are provided to the traction inverter at block 412. If the speed level is not greater than the threshold (determination block 404), the determination block 406 determines if the OVP signal is asserted. If the OVP signal is asserted (determination block 406) and there is no low-side switch fault (determination block 418), low-side on and high-side off control signals are provided to a traction inverter at block 422. In some example embodiments, block 422 corresponds to a second fault condition type called low-side ASC (to turn on the low-side switch).

If the OVP signal is asserted (determination block 406) and there is a low-side switch fault (determination block 418), high-side on and low-side off control signals are provided to the traction inverter at block 420. In some example embodiments, block 420 corresponds to a third fault condition type called high-side ASC (to turn on the high-side switch). In some example embodiments, the determination block 418 may use the switch fault signal to determine whether there is a low-side switch fault. If the OVP signal is not asserted (determination block 406) and the OCP signal is asserted (determination block 416), the high-side off and low-side off control signals are provided at block 410. If the OVP signal is not asserted (determination block 406) and the OCP signal is not asserted (determination block 416), the PWM control signals are provided at block 412.

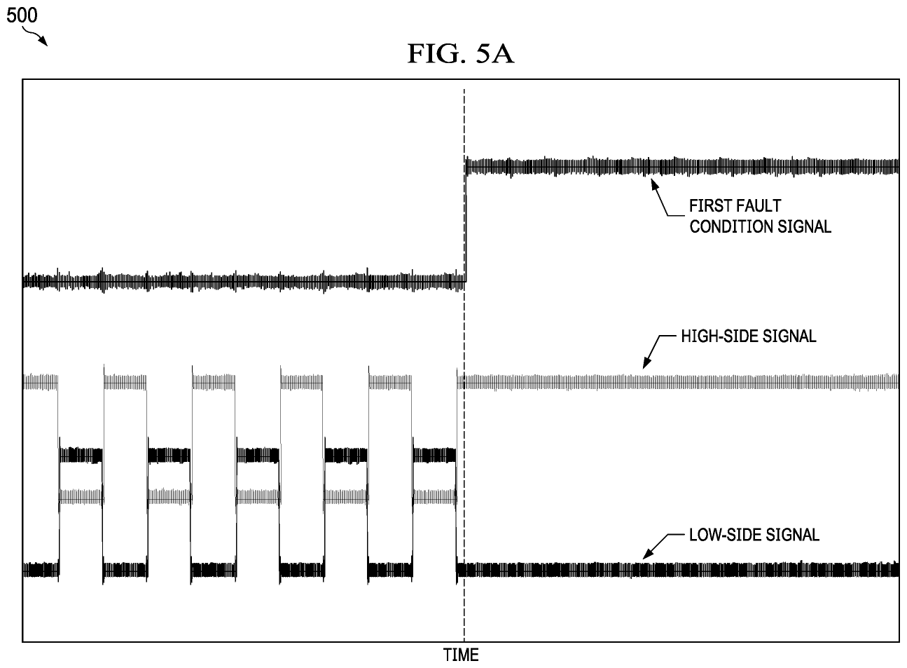

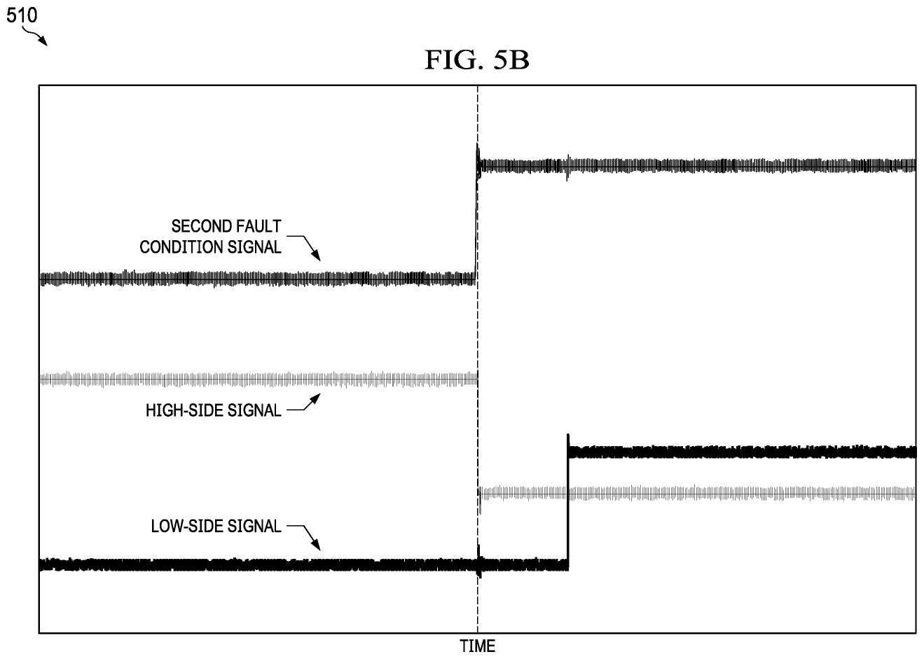

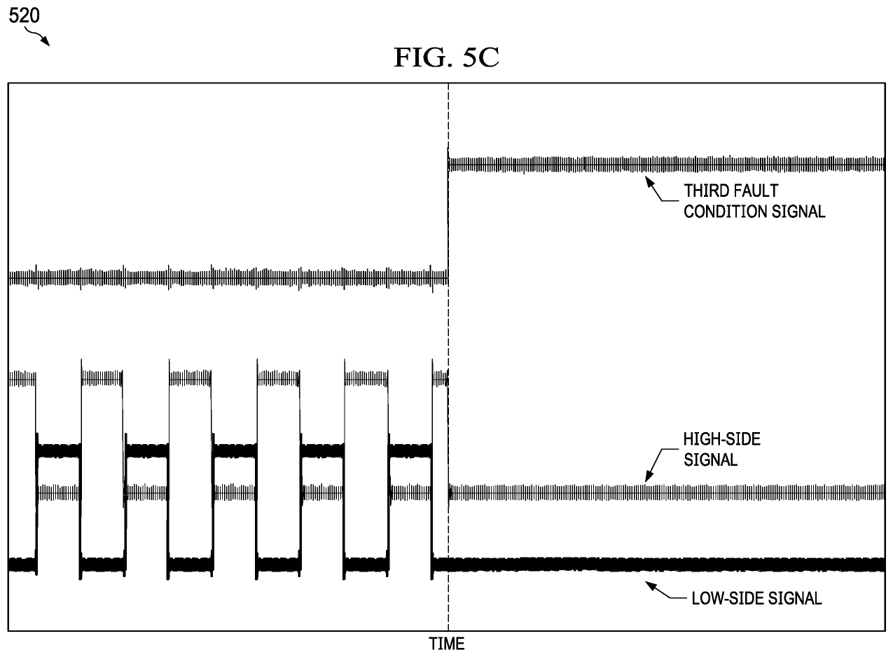

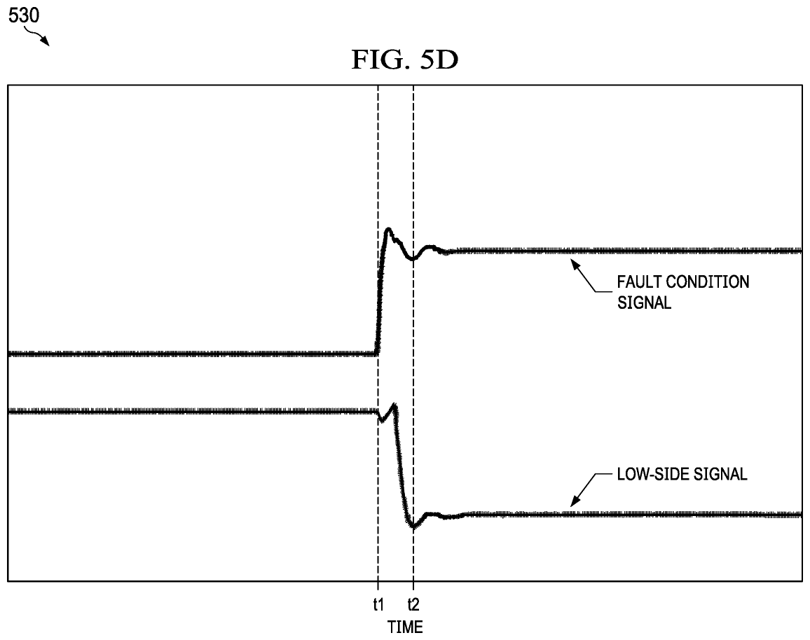

FIGS. 5A-5D are graphs 500, 510, 520, and 530 showing a fault condition waveform and related traction inverter protection signals in accordance with an example embodiment. In the graph 500 of FIG. 5A, a first fault condition signal (indicating a high-side ASC condition) is shown as well as a high-side signal (e.g., for a high-side switch of a traction inverter) and a low-side signal (e.g., for a low-side switch of a traction inverter). While the first fault condition signal is de-asserted, the high-side signal and the low-side signal are offset PWM control signals with the same duty cycle (e.g., a 50% duty cycle). In other words, when the high-side signal is high, the low-side signal is low and vice versa. After the first fault condition signal is asserted, the high-side signal is asserted and the low-side signal is de-asserted (e.g., a high-side ASC condition exists resulting in the operations of block 420 of FIG. 4).

In the graph 510 of FIG. 5B, a second fault condition signal (indicating a low-side ASC condition) is shown as well as a high-side signal and a low-side signal. While the second fault condition signal is de-asserted, the high-side signal is on and the low-side signal is off. After the second fault condition signal is asserted, the high-side signal is de-asserted immediately and the low-side signal is asserted (e.g., a low-side ASC condition exists resulting in the operations of block 422 of FIG. 4) after a delay. Relative to the graph 500 of FIG. 5A, the graph 510 of FIG. 5B is zoomed in (less than 1 cycle of the high-side signal and the low-side signal are shown).

In the graph 520 of FIG. 5C, a third fault condition signal (indicating a shut-down condition) is shown as well as a high-side signal, and a low-side signal. While the third fault condition signal is de-asserted, the high-side signal and the low-side signal are offset PWM control signals with the same duty cycle (e.g., a 50% duty cycle). In other words, when the high-side signal is high, the low-side signal is low and vice versa. After the third fault condition signal is asserted, the high-side signal is de-asserted and the low-side signal is de-asserted (e.g., a shut-down condition exists resulting the operations of block 410 of FIG. 4).

In the graph 530 of FIG. 5D, a fault condition signal and a low-side signal are shown. The fault condition signal is initially de-asserted before being asserted at time t1. In response to the fault condition signal being asserted at time t1, the low-side signal is de-asserted. In the graph 530, the fault condition signal and the low-side signal have steep slopes and transition by time t2 in response to a fault condition. By responding quickly to a fault condition, traction inverter protection is improved.

FIG. 6 is a flowchart showing a traction inverter protection method 600 performed by a microcontroller in accordance with an example embodiment. As shown, the method 600 includes generating PWM control signals for a traction inverter at block 602. At block 604, the method 600 detects if there is a fault condition associated with the traction inverter. At block 606, the method provides a traction inverter protection signal to the traction inverter if the fault condition is detected. At block 608, the method 600 provides the PWM control signals to the traction inverter if the fault condition is not detected.

In some example embodiments, detecting if there is a fault condition at block 604 includes: generating a speed level based on a motor position indicator; generating a switch fault signal based on a switch fault indicator; generating an overcurrent detection signal based on a current sense value and a threshold; generating an overvoltage detection signal on a voltage sense value and a threshold; and determining if there is a fault condition based on the speed level, the switch fault signal, the overcurrent detection signal, and the overvoltage detection signal. In some example embodiments, the method 600 also includes determining a fault condition type based on the speed level, the switch fault signal, the overcurrent detection signal, and the overvoltage detection signal; and adjusting the traction inverter protection signal based on the fault condition type.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-type metal-oxide-silicon field effect transistor (“MOSFET”) may be used in place of an n-type MOSFET with little or no changes to the circuit. Furthermore, other types of transistors may be used (such as bipolar junction transistors (BJTs)).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Unless otherwise stated, “about,” “approximately,” or “substantially” preceding a value means+/−10 percent of the stated value. Modifications are possible in the described examples, and other examples are possible within the scope of the claims.

What is claimed is:

1. An integrated circuit, comprising:
a control signal output;
a pulse-width modulation (PWM) subsystem with a PWM input and a PWM output, the PWM output configured to provide PWM control signals; and
configurable logic (CL) with a first CL input, a second CL input, and a CL output, the first CL input is coupled to the PWM output, the second CL input is adapted to receive a fault indicator, the CL output is coupled to the control signal output, and the CL is configured to provide the PWM control signals to the control signal output unless the fault indicator indicates a fault.

2. The integrated circuit of claim 1, wherein the CL is configured to provide low-side on and high-side off control signals to the control signal output responsive to the fault indicator indicating a speed level greater than a threshold, an overvoltage condition, and no low-side switch fault.

3. The integrated circuit of claim 1, wherein the CL is configured to provide high-side on and low-side off control signals to the control signal output responsive to the fault indicator indicating a speed level greater than a threshold, an overvoltage condition, and a low-side switch fault.

4. The integrated circuit of claim 1, wherein the CL is configured to provide high-side off and low-side off control signals to the control signal output responsive to the fault indicator indicating a speed level equal to or less than a threshold and at least one of an overvoltage condition and an overcurrent condition.

5. The integrated circuit of claim 1, wherein the CL is configured to provide high-side off and low-side off control signals to the control signal output responsive to the fault indicator indicating a speed level greater than a threshold, no overvoltage condition, and an overcurrent condition.

6. The integrated circuit of claim 1, further comprising a quadrature encoder pulse (QEP) module with an QEP input and a QEP output, the QEP input is configured to receive a motor position indicator, the QEP output is coupled to the second CL input, and the QEP module configured to provide a speed level at the QEP output responsive to the position indicator.

7. The integrated circuit of claim 1, further comprising a general programmable input/output (GPIO) module having a GPIO input and a GPIO output, the GPIO input adapted to receive a switch fault indicator associated with a traction inverter switch, the GPIO output coupled to the second CL input, and the GPIO configured to provide a switch fault signal at the GPIO output responsive to the switch fault indicator.

8. The integrated circuit of claim 1, further comprising a general programmable input/output (GPIO) module having a GPIO input and a GPIO output, the GPIO input adapted to receive a current sense value, the PIO output coupled to the second CL input, and the GPIO configured to provide an overcurrent condition signal at the GPIO output responsive to the current sense value being greater than a threshold.

9. The integrated circuit of claim 1, further comprising a programmable input/output (GPIO) module having a GPIO input and a GPIO output, the GPIO input adapted to receive a voltage sense value, the GPIO output coupled to the second CL input, and the GPIO configured to provide an overvoltage condition signal at the GPIO output responsive to the voltage sense value being greater than a threshold.

10. The integrated circuit of claim 1, further comprising a processor coupled to the PWM subsystem, wherein the processor has a processor input and a processor output, the processor input is adapted to receive motor control parameters, the processor output is coupled to the PWM input, and the processor is configured to provide PWM parameters at the processor output responsive to the received motor control parameters.

11. A system, comprising:
a microcontroller having:
a control signal output adapted to be coupled to a traction inverter;
a pulse-width modulation (PWM) subsystem configured to provide PWM control signals; and
configurable logic (CL) configured to:
receive the PWM control signals and a fault indicator; and
provide the PWM control signals to the control signal output unless the fault indicator indicates a fault.

12. The system of claim 11, wherein the CL is configured to provide low-side on and high-side off control signals to the control signal output responsive to the fault indicator indicating a speed level greater than a threshold, an overvoltage condition, and no low-side switch fault.

13. The system of claim 11, wherein the CL is configured to provide high-side on and low-side off control signals to the control signal output responsive to the fault indicator indicating a speed level greater than a threshold, an overvoltage condition, and a low-side switch fault.

14. The system of claim 11, wherein the CL is configured to provide high-side off and low-side off control signals to the control signal output responsive to the fault indicator indicating a speed level equal to or less than a threshold and at least one of an overvoltage condition and an overcurrent condition.

15. The system of claim 11, wherein the CL is configured to provide high-side off and low-side off control signals to the control signal output responsive to the fault indicator indicating a speed level greater than a threshold, no overvoltage condition, and an overcurrent condition.

16. The system of claim 11, wherein the microcontroller is configured to:
generate a speed level based on a motor position indicator;
generate a switch fault signal based on a switch fault indicator;
generate an overcurrent detection signal based on a current sense value and a threshold;
generate an overvoltage detection signal on a voltage sense value and a threshold; and
provide a traction inverter protection signal to the control signal output responsive to the speed level, the switch fault signal, the overcurrent detection signal, and the overvoltage detection signal indicating a fault condition.

17. The system of claim 11, further comprising:
a motor coupled to an output of the traction inverter; and
a battery coupled to the power supply input of the traction inverter, wherein the system is an electric vehicle.

18. A method, comprising:
generating, by a microcontroller, pulse-width modulation (PWM) control signals for a traction inverter;
detecting, by the microcontroller, if there is a fault condition associated with the traction inverter;
providing, by the microcontroller, a traction inverter protection signal to the traction inverter if the fault condition is detected; and
providing, by the microcontroller, the PWM control signals to the traction inverter if the fault condition is not detected.

19. The method of claim 18, wherein determining if there is a fault condition includes:
generating a speed level based on a motor position indicator;
generating a switch fault signal based on a switch fault indicator;
generating an overcurrent detection signal based on a current sense value and a threshold;
generating an overvoltage detection signal on a voltage sense value and a threshold; and
determining if there is a fault condition based on the speed level, the switch fault signal, the overcurrent detection signal, and the overvoltage detection signal.

20. The method of claim 19, further comprising:
determining a fault condition type based on the speed level, the switch fault signal, the overcurrent detection signal, and the overvoltage detection signal; and
adjusting the traction inverter protection signal based on the fault condition type.
